(19) United States
(12) Patent Application Publication
(10) Pub. No.: US 2026/0118611 A1
(43) Pub. Date: Apr. 30, 2026

(54) MULTI-CHANNEL LASER-TO-EXTERNAL MODULATOR ARRAY COUPLING ENABLED CO-PACKAGED OPTICS

(71) Applicant: OPTILAB, LLC, Phoenix, AZ (US)

(72) Inventors: Henry Hung, Paradise Valley, AZ (US); Xiaoyan Ying, Phoenix, AZ (US); Leijun Yin, Tempe, AZ (US); Ke Huang, Phoenix, AZ (US)

(21) Appl. No.: 18/933,822

(22) Filed: Oct. 31, 2024

(51) Int. Cl. G02B 6/43; G02B 6/42; H01L 23/00; H01L 23/498; H01L 25/16; H01S 3/00

(52) U.S. Cl. CPC G02B 6/43; G02B 6/428; G02B 6/4295; H01S 3/0085; H10W 70/635; H10W 90/00; H10W 90/701; H10W 90/725

(57) ABSTRACT

A multi-channel laser-to-external modulator array coupling enabled co-packaged optics (CPO) architectures. The CPO module integrates optical and electrical communication devices on a first-level substrate near a host switch ASIC, enabling high-bandwidth interconnects with reduced power consumption and minimized electrical losses. Configurations include remote lasers with blindmate optical connectors for safe replacement and integrated on-chip lasers for enhanced reliability in WDM systems. The module uses hybrid integrated modulators made of materials such as TFLN, InP, EO polymers, KTP, and BaTiO3. The optical engine, comprising a transmitter and receiver, connects via MPO connectors for efficient routing. The design supports efficient coupling and thermal management, suitable for switches, network interface cards, and AI/machine learning ASICs.

### BACKGROUND

### Field

Aspects of the present disclosure relate generally to optical modulators, and in particular, to a multi-channel laser-to-external modulator array coupling enabled co-packaged optics.

### Background

The integration of Co-Packaged Optics (CPO) and Linear Photonic Optical (LPO) technologies in data center switches has emerged as a strategic approach to reduce system-level power consumption and improve data transmission efficiency. CPO focuses on minimizing reliance on power-intensive electrical interconnects by combining photonic devices with high-performance electronics within a single package. This approach significantly shortens the SerDes distance, leading to a substantial reduction in power consumption. LPO, on the other hand, complements this by enabling precise linear photonic signal processing, further enhancing the overall system performance in high-speed data environments.

A critical component in both Co-Packaged Optics (CPO) and Linear Photonic Optical (LPO) systems is the laser source. For thin-film LiNbO3 (TFLN) and silicon photonics (SiPh) based optical engines, two primary types of laser sources are being developed: on-chip lasers and external lasers. Each type offers distinct advantages and presents specific challenges that must be addressed for optimal integration within these advanced photonic systems.

The use of an External Laser Source (ELS) presents a compelling solution for CPO and LPO applications due to its ease of maintenance, widespread availability, and the ability to support multiple channels. The monolithic integration of external laser sources with photonic devices offers benefits such as reduced parasitic capacitances, simplified packaging, and lower overall costs. Typically, an ELS includes a standardized Quad Small Form-factor Pluggable (QSFP) housing for optical transceivers, a multi-channel TOSA (Transmitter Optical Sub-assembly), and the necessary electronic circuits for TOSA control. However, the current methods for packaging multi-channel lasers are time-consuming and yield low results, making them labor-intensive and costly for market demands, particularly in high-density applications where LPO precision is critical.

Conversely, on-chip laser technology offers significant performance advantages, including proven reliability and the potential for wafer-scale manufacturing, burn-in, and testing. This approach simplifies subsystem-level design and enhances reliability by eliminating the need for fiber connections between the External Laser Source and the Photonic Integrated Circuit (PIC). This method is particularly advantageous in Linear Photonic Optical (LPO) systems, where maintaining precise alignment and minimizing optical losses is essential. However, manufacturing, assembling, and aligning discrete lasers on the chip become increasingly challenging as the number of laser channels and bandwidth requirements grow, particularly in densely integrated CPO and LPO environments.

The present invention aims to provide more straightforward and efficient packaging solutions for TFLN and SiPh-enabled CPO and LPO systems based on both external and on-chip laser integration methods. By addressing the challenges associated with these laser technologies, this invention seeks to enhance the performance, reliability, and cost-effectiveness of integrated photonic architectures, thereby advancing the capabilities of next-generation data centers and high-speed communication networks.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

An aspect of the disclosure relates to a co-packaged optics module. The co-packaged optics module includes a first-level substrate integrating optical and electrical communication devices; a host switch ASIC positioned on the first-level substrate; an optical engine comprising a modulator array, drivers, a PIN photodiode array, and TIAs, wherein the modulator array is composed of a hybrid integrated electro-optical thin film; a laser coupled to the modulator array, wherein the laser can be integrated or situated remotely from the modulator array; and MPO connectors for routing optical signals from the optical engine to external devices.

Another aspect of the disclosure relates to a method. The method includes integrating a laser array on a micro-optical bench; aligning the laser array to a focusing lens array using alignment marks; and coupling the focused beam from the laser array into a fiber array positioned in V-grooves.

Another aspect of the disclosure relates to a co-packaged optics module for wavelength division multiplexing (WDM) systems. The co-packaged optics module includes an integrated on-chip CWDM laser array flip-chip bonded onto a substrate; a modulator array receiving light from the CWDM laser array via mode converters; and a multiplexer for combining modulated light before outputting through a mode converter.

Another aspect of the disclosure relates to a method for thermal management in a co-packaged optics module. The method includes positioning a remote laser at a faceplate of the module to separate its thermal environment from the co-packaged switch ASIC; and using a thermoelectric cooler (TEC) beneath the laser array to maintain optimal operating temperatures.

Another aspect of the disclosure relates to a thin-film modulator based co-packaged optics module. The co-packaged optics module includes a host switch ASIC, a hybrid-integrated optical engine including a receiver comprising an optical demultiplexer configured to receive an input optical signal, a PIN array optically coupled to outputs of the optical demultiplexer, a set of TIAs electrically coupled to outputs of the PIN array, wherein the host switch ASIC includes inputs electrically coupled to the set of TIAs; and a transmitter, comprising: a set of drivers including inputs electrically coupled to the host switch ASIC, an electro-optical (EO) thin-film modulator including a first set of inputs coupled to outputs of the set of drivers, and a second set of inputs coupled to a laser array, and an optical multiplexer including a set of inputs optically coupled to the EO modulator, and an output to generate an output optical signal.

Another aspect of the disclosure relates to a thin-film modulator based co-packaged optics module. The co-packaged optics module includes a transmitter, comprising: a laser array, a hybrid integrated modulator disposed on the substrate and optically coupled to the laser array via mode converters, a multi-mode interference (MMI) splitter including inputs coupled to hybrid integrated modulator, a first set of outputs coupled to a photodiode (PD) array, and a second set of outputs coupled to a multiplexer arrayed waveguide, and a first mode converter coupled to the multiplexer arrayed waveguide, the first mode converter configured to output a first modulated optical signal; and a receiver, comprising: a second mode converter configured to receive a second modulated optical signal, a demultiplexer arrayed waveguide grating optically coupled to the second mode converter, a set of optical waveguides coupled to the demultiplexer arrayed waveguide grating, and a photodiode (PD) array coupled to the set of waveguides; and a substrate to which the transmitter and the receiver are integrated.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the description embodiments are intended to include all such aspects and their equivalents.

### BRIEF DESCRIPTION OF THE DRAWINGS

FIGS. 1A-1B illustrate a block diagram and side view of an exemplary CPO with a remote laser in accordance with an aspect of the disclosure.

FIGS. 2A-2B illustrate block diagram and side view of an exemplary CPO with an on-chip laser in accordance with another aspect of the disclosure.

FIGS. 3A-3B illustrate perspective and side views of an exemplary coupling configuration of a laser array integrated on micro-optical bench in accordance with another aspect of the disclosure.

FIGS. 4A-4B illustrate perspective and side views of another exemplary coupling configuration of a laser array integrated on micro-optical bench in accordance with another aspect of the disclosure.

FIGS. 5A-5B illustrate top and side views of an exemplary hybrid integrated laser array with combined outputs in accordance with another aspect of the disclosure.

FIG. 6 illustrates a top view of an exemplary hybrid integrated laser array with combined outputs and optical isolator in accordance with another aspect of the disclosure.

FIGS. 7A-7B illustrate top and side views of an exemplary CPO powered by remote CW laser in accordance with another aspect of the disclosure.

FIG. 8 illustrates a top view of an exemplary CPO powered by remote multi-outputs CWDM laser in accordance with another aspect of the disclosure.

FIG. 9 illustrates a top view of an exemplary CPO powered by remote combined outputs laser in accordance with another aspect of the disclosure.

FIGS. 10A-10B illustrate top and side views of an exemplary CPO powered by integrated on-chip laser in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

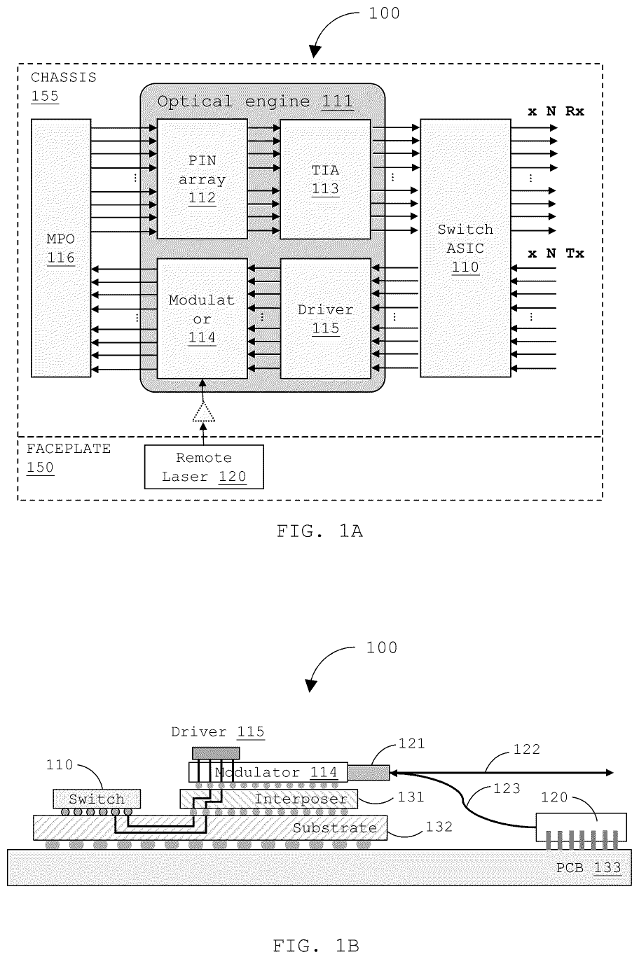

FIG. 1A illustrates a block diagram of an exemplary co-packaged optics (CPO) module 100 with a remote laser 120 in accordance with an aspect of the disclosure. The CPO module 100 integrates optical and electrical communication devices on the same first-level substrate as the host switch ASIC 110, providing high bandwidth interconnects with significant power savings. By positioning the optical engine 111, which includes an optical transmitter (comprising the modulator array 114 and drivers 115) and an optical receiver (comprising the PIN photodiode array 112 and TIAs 113), in close proximity to the host switch ASIC 110, high-speed electrical channel losses and impedance discontinuities are minimized. This configuration enables the use of higher speed, and lower power off-chip I/O drivers.

The modulator array 114 is composed of thin film electro-optical materials (TFLN, Barium Titanate Nanostructure (BTO), or electro-optic polymers) integrated with other optical components and electronic devices using the Silicon Photonics platform. The remote laser 120, equipped with a blindmate optical connector to facilitate safe field replacement in case of failure, generates a high level of optical power (>˜15 decibel-milliwatts (dBm) per fiber) to support multiple optical modulators of the modulator array 114. The laser can be either continuous wave (CW) or CW-Wavelength Division Multiplexing (CW-WDM), depending on the application. The CPO 100 interfaces are routed to MPO (Multi-fiber Push On) connectors 116, which feature a linear array of fibers in a single ferrule. This CPO optical engine 111 to front-panel routing 116 supports both traditional fiber and flexible printed fiber (FPF) solutions.

The remote laser 120 is primarily designed for CPO applications, which may include the use of external lasers to provide optical power to optical engines (OEs) incorporated in switches, network interface cards, AI and machine learning application-specific integrated circuits (ASICs), and more. The major benefits of this form factor include reliably providing a replaceable light source package, safely coupling that light to maintain the system as an International Electrotechnical Commission (IEC) 60825-2 Hazard Level 1 product, and separating the thermal environment of the laser from that of the co-packaged switch ASIC 110 assembly. Lasers have historically shown significantly lower maximum reliable junction temperatures than silicon dies (including silicon photonic circuit elements and germanium photodetectors). Thus, by placing the remote laser 120 at a faceplate 150 of a chassis 155 housing or enclosing the CPO 100 systems (away from the heat of the co-packaged switch ASIC 110 and OE 111), a more efficient cooling solution can be designed, achieving greater reliability with the fail-safe of a field-replaceable pluggable module in case of laser failure.

FIG. 1B illustrates a side view of an exemplary CPO 100 with a remote laser 120 in accordance with another aspect of the disclosure. The driver chip 115 can be flip-chip bonded to the hybrid integrated modulator 114, and light can be coupled with a fiber array 121 for input 123 from the remote laser source 120 or output 122 to the MPO 116. The modulator 114 and other optical components can be integrated onto the same interposer 131 for connection to the switch ASIC 110 on the same package substrate 132 on the host PCB 133.

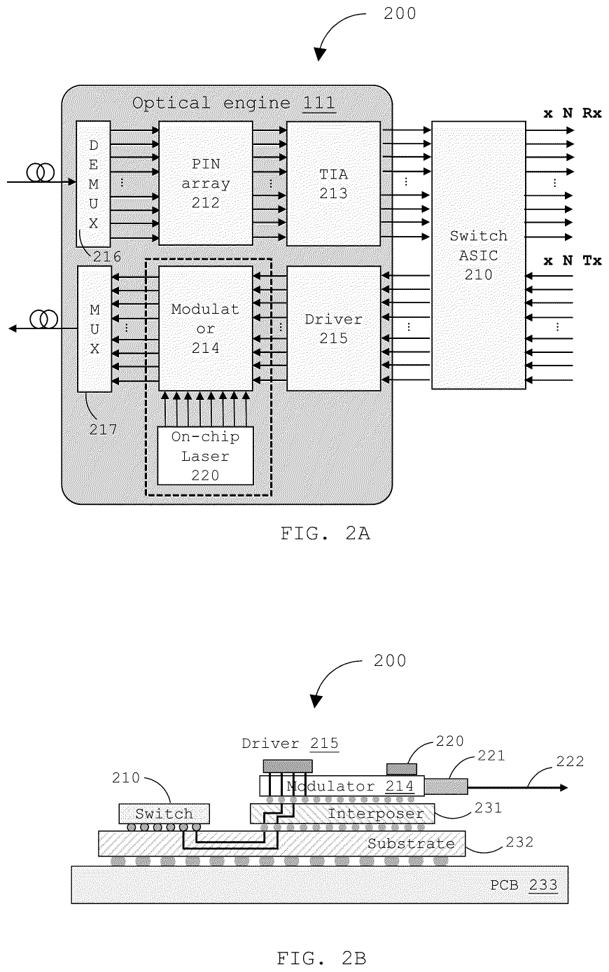

FIG. 2A illustrates a block diagram of an exemplary co-packaged optics (CPO) module 200 with an integrated on-chip laser 220 in accordance with another aspect of the disclosure. The on-chip laser 220 offers significant performance advantages and proven reliability, enabling true wafer-scale manufacturing, burn-in, and testing. This results in higher subsystem-level simplicity and reliability. This approach eliminates the need for fibers connecting the external laser source and the photonic integrated circuit (PIC). It combines data signals received from the transceiver into one beam of light containing multiple optical wavelengths, which are transmitted simultaneously over a single fiber through a multiplexer 217. At the receiver side, a demultiplexer 216 receives the multiple wavelengths and separates them back into individual data channels.

One of the significant advantages of integrating the laser onto chip is for Wavelength Division Multiplexing (WDM) systems, where multiple wavelengths are used to transmit data simultaneously. Flip-chip bonding technology offers a compact and precise method for mounting lasers directly onto substrates, enhancing performance by reducing interconnect lengths and improving alignment with optical components, allowing higher integration density and scalability, enabling the addition of multiple laser channels without significantly increasing the size or complexity of the module. Additionally, integrated on-chip lasers improve coupling efficiency and reduce crosstalk between channels, which may be desirable for maintaining signal integrity in high-channel WDM systems. Both the multiplexer 231 and demultiplexer 232 can be implemented on the Silicon Photonics platform together with the PIN array 212 and modulator array 214.

FIG. 2B illustrates a side view of an exemplary CPO 200 with an integrated on-chip laser 220 in accordance with another aspect of the disclosure. Light is coupled into the modulator 214 through a flip-chip bonded on-chip laser 220. The driver chip 215 can be flip-chip bonded to the hybrid integrated modulator 214, and light can be coupled with a fiber array 221 for output 222. The modulator 214 and other optical components can be integrated onto the same interposer 231, which connects to the switch ASIC 210 on the same package substrate 232 on the host PCB 233.

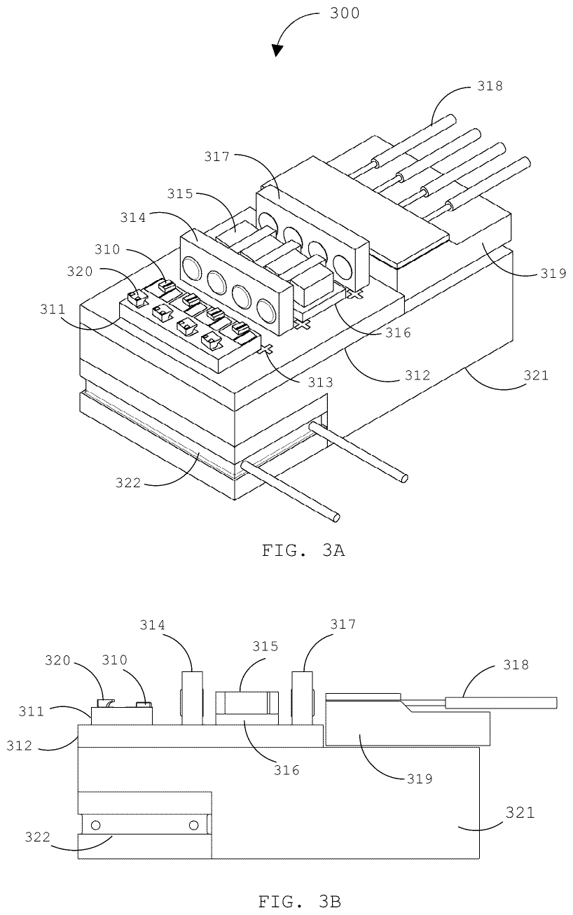

FIG. 3A illustrates a perspective view of an exemplary coupling configuration of a laser array integrated on a micro-optical bench 300 in accordance with another aspect of the present disclosure. The laser array 310, which may comprise continuous wave (CW) or electro-absorption modulated lasers (EML), and the monitor photodiode (PD) 320 are passively bonded to the first-level substrate 312, where the bonding may be achieved through eutectic bonding, epoxy bonding, or any other feasible bonding method. These components 310 and 320 are further passively aligned to the focusing lens array 314, which may include micro silicon lenses or molded high-index glass lenses, using alignment marks 313. The focused beam traverses through the isolator array 315, which may include magnets or be magnet-free, prior to being actively coupled into the fiber array 318. The fiber array 318 is retained in V-grooves 319, and the beam is further focused through an additional focusing lens array 317. The entire optical assembly is positioned on a metal heat sink 321, with a thermoelectric cooler (TEC) 322 embedded beneath the laser array 310 to facilitate cooling. This configuration is designed to ensure efficient coupling and thermal management, thereby enhancing the performance and reliability of the integrated system.

FIG. 3B illustrates a side view of the coupling configuration depicted in FIG. 3A. The laser array 310 and monitor photodiode (PD) 320 disposed on a second-level substrate 311, focusing lens array 314, alignment marks 313, isolator array 315 disposed on a substrate 316, fiber array 318, V-grooves 319, focusing lens array 317, metal heat sink 321, and thermoelectric cooler (TEC) 322 are shown from the side perspective.

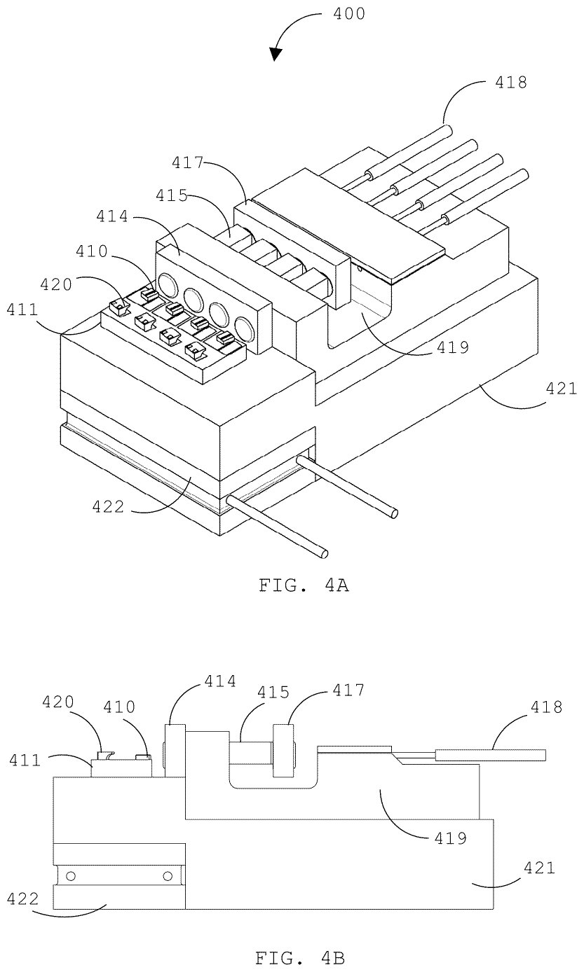

FIG. 4A illustrates a perspective view of another exemplary coupling configuration of a laser array integrated on a micro-optical bench 400 in accordance with another aspect of the disclosure. This configuration is similar to the configuration depicted in FIGS. 3A and 3B (e.g., similar components are numbered the same with the most significant digital being a “4” in FIGS. 4A-4B). The laser array 410, which may comprise continuous wave (CW) or electro-absorption modulated lasers (EML), and the monitor photodiode (PD) 420 are passively bonded to the substrate 411, where the bonding may be achieved through eutectic bonding, epoxy bonding, or any other feasible bonding method. These components are further passively aligned to the focusing lens array 414, which may include micro silicon lenses or molded high-index glass lenses, using alignment marks. The isolator 415 and the collimating lens 417 are either passively or actively preassembled to the fiber array 418, which is seated in V-grooves 419. These components are then actively aligned to the focused beam from the focusing lens array 414. The entire optical assembly is positioned on a metal heat sink 421, with a thermoelectric cooler (TEC) 422 embedded beneath the laser array 410 to facilitate cooling.

FIG. 4B illustrates a side view of the coupling configuration depicted in FIG. 4A. The laser array 410, monitor photodiode (PD) 420, and substrate 411 are shown, where the laser array and photodiode are passively bonded to the substrate using eutectic bonding, epoxy bonding, or any other feasible bonding method. The focusing lens array 414, isolator 415, collimating lens 417, and fiber array 418 seated in V-grooves 419 are also depicted. The entire optical assembly is mounted on a metal heat sink 421, with a thermoelectric cooler (TEC) 422 embedded beneath the laser array 410 to facilitate cooling. This side view emphasizes the spatial arrangement and alignment of the components, ensuring efficient coupling and thermal management within the integrated system.

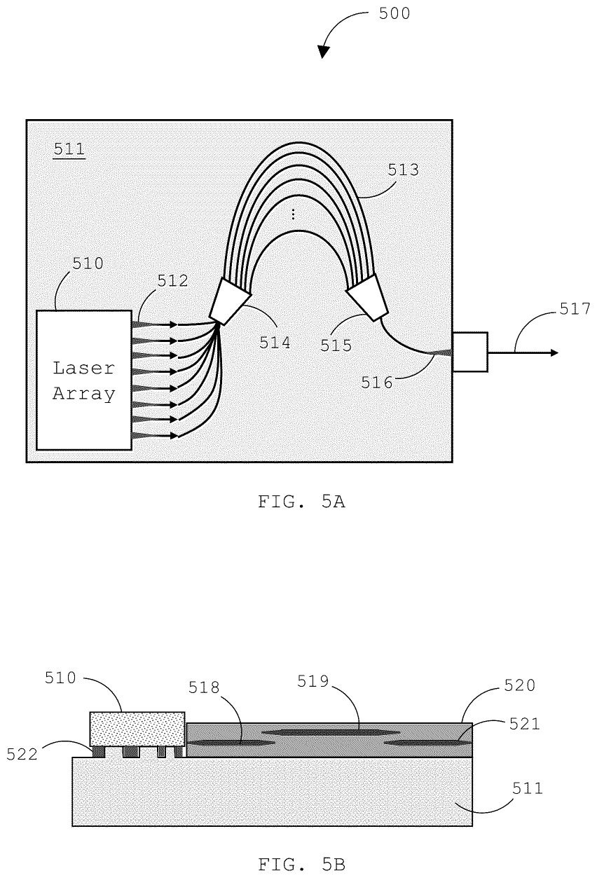

FIG. 5A illustrates a top view of an exemplary hybrid integrated laser array with multiple outputs 500 in accordance with another aspect of the disclosure. The laser array 510 is flip-chip bonded onto the substrate 511, which can be composed of silicon, SiO2, or any hybrid bonded substrates, or any other feasible substrates. The mode converter 512 couples the laser output into the substrate waveguides. The input slab region 514, the arrayed waveguides 513, and the output slab region 515 together form the arrayed waveguide gratings (AWG), which are commonly used as optical (de) multiplexers in wavelength division multiplexed (WDM) systems. The combined light is then coupled to the output fiber array 517 through a mode converter 516.

FIG. 5B is a side view of the configuration illustrated in FIG. 5A. The laser 510 is shown, with solder 522 beneath the laser chip bonding it to the substrate 511. The input mode converter waveguide 518 couples to the arrayed waveguide gratings (AWG) waveguides 519, which further couple to the output mode converter 521. The waveguides 518, 519, and 520 can be made of silicon nitride (SiN), amorphous silicon, polymer, or any other feasible low-loss materials. The cladding layer 520, which encapsulates the waveguides, can be composed of SiO2, polymer, or any other suitable materials.

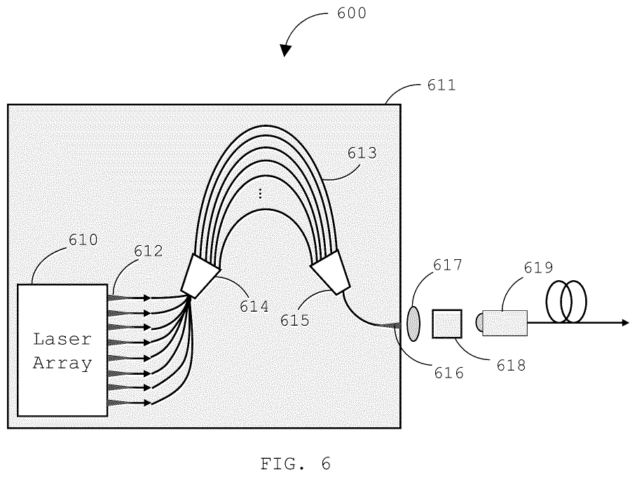

FIG. 6 illustrates a top view of an exemplary hybrid integrated laser array with combined outputs and isolator 600 in accordance with another aspect of the disclosure. This configuration is similar to the one depicted in FIG. 5A, with the addition of a free space isolator 618. The laser array 610 is flip-chip bonded onto the substrate 611, which can be composed of silicon, SiO2, or any hybrid bonded substrates, or any other feasible substrates. The mode converter 612 couples the laser output into the substrate waveguides. The input slab region 614, the arrayed waveguides 613, and the output slab region 615 together form the arrayed waveguide gratings (AWG), which are commonly used as optical (de) multiplexers in wavelength division multiplexed (WDM) systems. The output combined light from mode converter 616 is then coupled from the chip to the isolator 618 through a micro focusing lens 617, before being coupled into the collimator 619. This configuration is particularly suitable for applications that require optical isolators, such as preventing back reflections and reducing noise in optical communication systems. By integrating the isolator within the hybrid design, this configuration ensures efficient coupling and thermal management while providing the necessary isolation to enhance the performance and reliability of the optical system. The integration of the free space isolator 618 helps maintain signal integrity and improves the overall stability of the system, making it ideal for high-precision and high-performance optical applications.

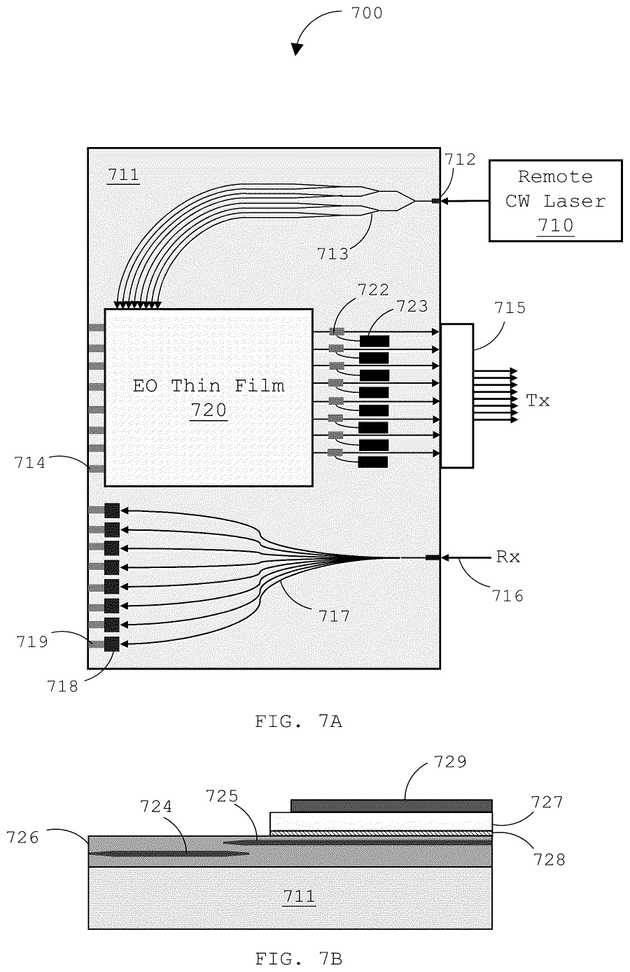

FIG. 7A illustrates a top view of an exemplary co-packaged optics (CPO) module powered by a remote continuous wave (CW) laser in accordance with another aspect of the disclosure. The CW light from the remote laser 710 is coupled to the photonic circuit integrated on substrate 711, which can be composed of silicon (Si), silicon dioxide (SiO2), or any other suitable materials. The light from the remote laser 710 is coupled to a splitter 713 through a mode converter 712, before being directed into the hybrid integrated modulator 720. The modulator 720 can be made of thin-film lithium niobate (LiNbO3), indium phosphide (InP), electro-optic (EO) polymer, potassium titanyl phosphate (KTP), barium titanate (BaTiO3), or any other suitable materials. The modulator 720 is powered by electrodes 714, which are connected to RF connectors or drivers at the edge of the substrate 711. The modulated light from the modulator 720 is monitored by a photodiode (PD) array 723 through a multi-mode interference (MMI) splitter 722. The output light is then coupled to the transmission (TX) fiber array 715. Additionally, the receiver can be integrated onto the same substrate 711. Input light 716 is coupled into the receiver side waveguide splitter 717, before being received by flip-chip bonded high-speed photodiodes (PD) 718, which are powered by electrodes 719.

FIG. 7B is a side view of the configuration illustrated in FIG. 7A, where light from the remote laser 710 is coupled to the photonic integrated circuits on substrate 711. The first stage mode converter 724 couples the light to a second stage mode size converter 725, which then couples the light into the thin-film hybrid integrated modulator 727. The modulator 727 is bonded to the substrate 711 through an intermediate bonding layer 728, which can be composed of polymer, silicon dioxide (SiO2), or other suitable materials. The electrodes 729 are positioned on top of the modulator 727 to provide the necessary electrical control. This side view emphasizes the sequential coupling of light through the mode converters and into the modulator, highlighting the layered structure and integration of the components.

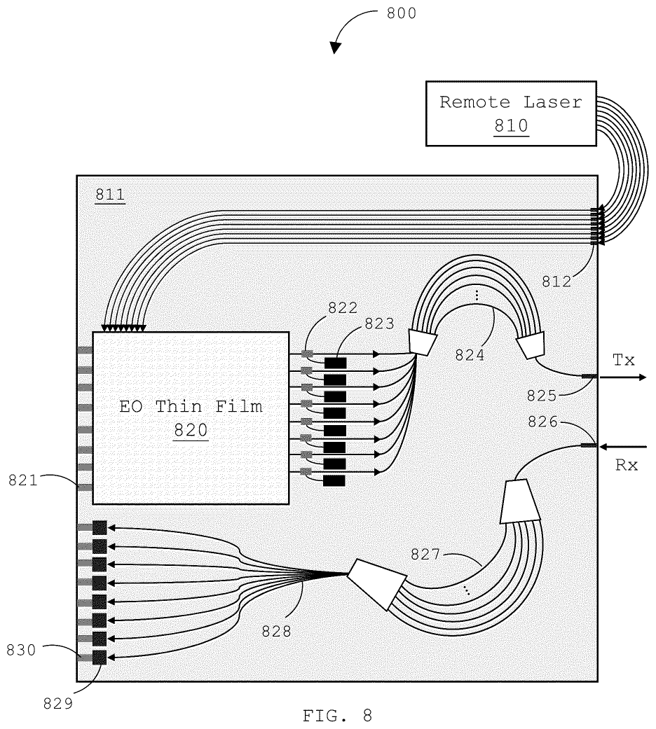

FIG. 8 illustrates a top view of an exemplary co-packaged optics (CPO) module 800 powered by a remote multi-output coarse wavelength division multiplexing (CWDM) laser 810 in accordance with another aspect of the disclosure. The output from the CWDM laser 810 is coupled into the photonic integrated circuit (PIC) integrated on substrate 811, which can be composed of silicon (Si), silicon dioxide (SiO2), or any other suitable materials, through a mode converter 812. The light is then directed into the hybrid integrated thin-film modulator 820. The modulator 820 can be made of thin-film lithium niobate (LiNbO3), indium phosphide (InP), electro-optic (EO) polymer, potassium titanyl phosphate (KTP), barium titanate (BaTiO3), or any other suitable materials. The modulated light is monitored by a photodiode (PD) array 823 via a multi-mode interference (MMI) splitter 822, and subsequently combined through a multiplexer arrayed waveguide grating (MUX AWG) 824 before being output through a mode converter 825. On the receiver side, the input light is coupled into the PIC through mode converter 826, fed into a demultiplexer arrayed waveguide grating (DEMUX AWG) 827, and split through output waveguides 828 into a high-speed PD array 829, which is powered by electrodes 830.

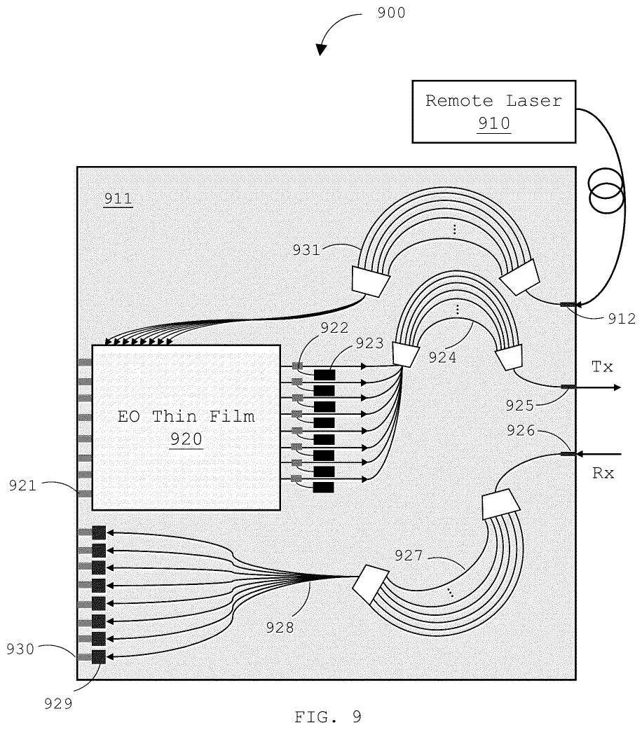

FIG. 9 illustrates a top view of an exemplary co-packaged optics (CPO) module 900 powered by a remote combined output coarse wavelength division multiplexing (CWDM) laser 910 in accordance with another aspect of the disclosure. This configuration is similar to the one depicted in FIG. 8, with key differences. The output from the CWDM laser 910 is combined and coupled into the photonic integrated circuit (PIC) integrated on substrate 911, which can be composed of silicon (Si), silicon dioxide (SiO2), or any other suitable materials, through a mode converter 912. On the chip, an arrayed waveguide grating (AWG) demultiplexer 931 is used to separate the input laser into individual channels. The separated light is then directed into the hybrid integrated thin-film modulator 920. The modulator 920 can be made of thin-film lithium niobate (LiNbO3), indium phosphide (InP), electro-optic (EO) polymer, potassium titanyl phosphate (KTP), barium titanate (BaTiO3), or any other suitable materials. The modulated light is monitored by a photodiode (PD) array 923 via a multi-mode interference (MMI) splitter 922, and subsequently combined through a multiplexer arrayed waveguide grating (MUX AWG) 924 before being output through a mode converter 925. On the receiver side, the input light is coupled into the PIC through mode converter 926, fed into a demultiplexer arrayed waveguide grating (DEMUX AWG) 927, and split through output waveguides 928 into a high-speed PD array 929, which is powered by electrodes 930.

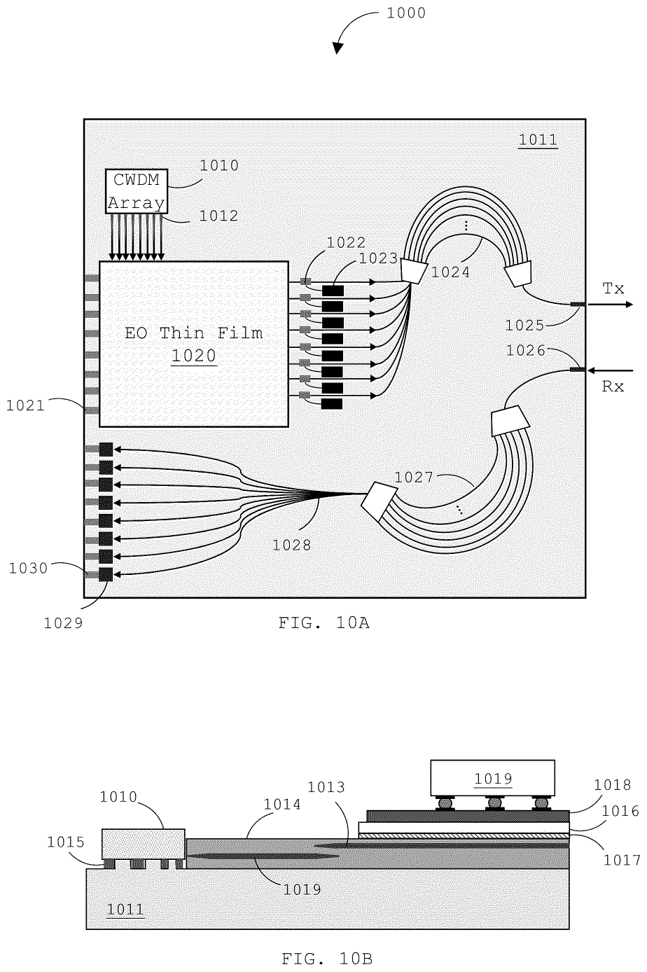

FIG. 10A illustrates a top view of an exemplary co-packaged optics (CPO) module similar to the configuration depicted in FIG. 8, with a key difference being the use of an integrated coarse wavelength division multiplexing (CWDM) laser array 1010. This laser array 1010 is flip-chip bonded onto the substrate 1011, which can be composed of silicon (Si), silicon dioxide (SiO2), or any other suitable materials. The output light from the CWDM laser array 1010 is coupled into the photonic integrated circuit (PIC) waveguides through mode converters 1012. The light is then directed into the hybrid integrated thin-film modulator 1020. The modulator 1020 can be made of thin-film lithium niobate (LiNbO3), indium phosphide (InP), electro-optic (EO) polymer, potassium titanyl phosphate (KTP), barium titanate (BaTiO3), or any other suitable materials. The modulated light is monitored by a photodiode (PD) array 1023 via a multi-mode interference (MMI) splitter 1022, and subsequently combined through a multiplexer arrayed waveguide grating (MUX AWG) 1024 before being output through a mode converter 1025. On the receiver side, the input light is coupled into the PIC through mode converter 1026, fed into a demultiplexer arrayed waveguide grating (DEMUX AWG) 1027, and split through output waveguides 1028 into a high-speed PD array 1029, which is powered by electrodes 1030. This configuration enables efficient coupling and processing of optical signals, leveraging the integration of the CWDM laser array, modulator, and photodiode arrays within the PIC on the substrate.

FIG. 10B is a side view of the configuration illustrated in FIG. 10A. The CWDM laser array 1010 is shown, bonded to the substrate 1011 using solder 1015. The output light from the CWDM laser array is coupled into the photonic integrated circuit (PIC) waveguide through a first stage mode converter 1012. The light then passes through a second stage mode size converter 1013, which couples the light into the thin-film modulator 1016. Both the first stage mode converter 1012 and the second stage mode converter 1013 are embedded in the cladding layer 1014. The modulator 1016 is bonded to the substrate 1011 through an intermediate bonding layer 1017, which can be composed of polymer, silicon dioxide (SiO2), or other suitable materials. The modulator is driven by the driver 1019, and the necessary electrical control is provided by electrodes 1018 positioned on top of the modulator 1016. This side view highlights the layered structure and the sequential coupling of light through the mode converters and into the modulator, ensuring efficient integration and functionality of the components within the system.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A co-packaged optics module comprising:
a first-level substrate integrating optical and electrical communication devices;
a host switch ASIC positioned on the first-level substrate;
an optical engine comprising a modulator array, drivers, a PIN photodiode array, and TIAs, wherein the modulator array is composed of a hybrid integrated electro-optical thin film;
a laser coupled to the modulator array, wherein the laser can be integrated or situated remotely from the modulator array; and
MPO connectors for routing optical signals from the optical engine to external devices.

2. The co-packaged optics module of claim 1, wherein the integrated laser is selected from a distributed feedback (DFB) laser or an electro-absorption modulated laser (EML) configured to operate without external modulators in the optical engine.

3. The co-packaged optics module of claim 1, wherein the remote laser is selected from the group including a photonic integrated circuit-based laser or a traditional discrete components-based laser.

4. The co-packaged optics module of claim 3, wherein the photonic integrated circuit-based multichannel laser can utilize either an isolator array for each channel or a single isolator positioned after the light is combined using a photonic integrated circuit arrayed waveguide grating.

5. The co-packaged optics module of claim 1, wherein either the remote laser or the integrated laser can operate as either a single wavelength laser or a wavelength division multiplexing (WDM) laser composed of multiple continuous wave (CW) lasers, each operating at different wavelengths.

6. The co-packaged optics module of claim 1, wherein the remote laser is positioned at a faceplate of the module to enhance thermal management by minimizing heat exposure from the host switch ASIC.

7. The co-packaged optics module of claim 1, wherein the thin-film modulator array and other optical components are integrated on an interposer that connects to the host switch ASIC.

8. The co-packaged optics module of claim 1, wherein the modulator array is hybrid integrated, comprising thin-film materials selected from the group consisting of lithium niobate (TFLN), indium phosphide (InP), electro-optic polymers, potassium titanyl phosphate (KTP), or barium titanate (BaTiO3), bonded onto an embedded waveguide photonic integrated circuit (PIC) substrate.

9. The co-packaged optics module of claim 1, wherein the optical engine includes an on-chip multiplexer for combining multiple optical wavelengths transmitted over a single fiber and a demultiplexer for separating received optical wavelengths into individual data channels.

10. The co-packaged optics module of claim 1, further comprising flip-chip bonded driver chips on the modulator array to enhance performance by reducing interconnect lengths.

11. A method for coupling multiple laser channels in a co-packaged optics module, comprising:
integrating a laser array on a micro-optical bench;
passively aligning the laser array to a collimating array using alignment marks; and
coupling the focused beam from the laser array into a fiber array positioned in V-grooves with pre-installed isolator and focusing lens array.

12. A co-packaged optics module for wavelength division multiplexing (WDM) systems, comprising:
an integrated on-chip CWDM laser array flip-chip bonded onto a substrate;
a modulator array receiving light from the CWDM laser array via mode converters; and
a multiplexer for combining modulated light before outputting through a mode converter.

13. The co-packaged optics module of claim 12, further comprising a demultiplexer for separating received CWDM signals into individual data channels before being processed by a high-speed photodiode array.

14. The co-packaged optics module of claim 12, wherein the substrate is composed of silicon, silicon dioxide (SiO2), or any hybrid bonded substrates suitable for integrated photonic circuits.

15. The co-packaged optics module of claim 12, wherein the output from the CWDM laser array is coupled to the modulator array through sequential mode converters embedded in the cladding layer of the substrate.

16. The co-packaged optics module of claim 10, wherein the modulator array is driven by flip-chip bonded driver chips and controlled by electrodes positioned on top of the modulator.

17. A thin-film modulator based co-packaged optics module comprising:
a host switch ASIC;
a hybrid-integrated optical engine, comprising:
a receiver, comprising
an optical demultiplexer configured to receive an input optical signal;
a PIN array optically coupled to outputs of the optical demultiplexer;
a set of TIAs electrically coupled to outputs of the PIN array, wherein the host switch ASIC includes inputs electrically coupled to the set of TIAs; and
a transmitter, comprising:
a set of drivers including inputs electrically coupled to the host switch ASIC;
an electro-optical (EO) thin-film modulator including a first set of inputs coupled to outputs of the set of drivers, and a second set of inputs coupled to a laser array; and
an optical multiplexer including a set of inputs optically coupled to the EO modulator, and an output to generate an output optical signal.

18. The thin-film modulator co-packaged optics module of claim 17, further comprising a substrate, wherein the host switch ASIC is disposed on the substrate, wherein the EO modulator is disposed on the substrate via an interposer, wherein the set of drivers and the laser array are mounted on the substrate via the EO modulator and interposer.

19. The thin-film modulator co-packaged optics module of claim 17, wherein the optical demultiplexer is integrated on the same photonic integrated circuit (PIC) substrate as the thin-film modulator, which is hybrid-integrated onto the substrate, and wherein the substrate includes mode converters to facilitate spot size transitions between the various components.

20. A co-packaged optics module comprising:
a transmitter, comprising:
a laser array;
a hybrid integrated modulator disposed on the substrate and optically coupled to the laser array via mode converters;
a multi-mode interference (MMI) splitter including inputs coupled to hybrid integrated modulator, a first set of outputs coupled to a photodiode (PD) array, and a second set of outputs coupled to a multiplexer arrayed waveguide; and
a first mode converter coupled to the multiplexer arrayed waveguide, the first mode converter configured to output a first modulated optical signal; and
a receiver, comprising:
a second mode converter configured to receive a second modulated optical signal;
a demultiplexer arrayed waveguide grating optically coupled to the second mode converter;
a set of optical waveguides coupled to the demultiplexer arrayed waveguide grating; and
a photodiode (PD) array coupled to the set of waveguides; and
a substrate to which the transmitter and the receiver are integrated.
